(19) United States
(12) Patent Application Publication
(10) Pub. No.: US 2025/0336779 A1
(43) Pub. Date: Oct. 30, 2025

(54) Package

(71) Applicant: GaNrich Semiconductor Corporation, Hsinchu County (TW)

(72) Inventors: Jia-Tay Kuo, Hsinchu County (TW); Chen-Yu Wang, Taoyuan City (TW); Sheng-Po Wang, Taoyuan City (TW); Chiao Fu, Hsinchu County (TW)

(73) Assignee: GaNrich Semiconductor Corporation, Hsinchu County (TW)

(21) Appl. No.: 19/183,948

(22) Filed: Apr. 21, 2025

(30) Foreign Application Priority Data
Apr. 25, 2024 (TW) 113115508

(51) Int. Cl. H01L 23/495; H01L 23/00; H01L 23/31; H01L 25/16; H10D 80/20

(52) U.S. Cl. CPC H01L 23/49562; H01L 23/3121; H01L 25/16; H10D 80/213; H10D 80/215; H10D 80/231; H10D 80/251; H01L 24/48; H01L 2224/48137; H01L 2224/48225; H01L 2924/1033; H01L 2924/12035; H01L 2924/1205; H01L 2924/1207; H01L 2924/1306; H01L 2924/13064

(57) ABSTRACT

The present disclosure discloses a package including a first support portion, a second support portion, and multiple pins. The first support portion includes a first upper metal layer and a first lower metal layer, wherein the first lower metal layer is connected to and overlaps with the first upper metal layer, corresponding to the position of the first upper metal layer. The second support portion is laterally separated from the first support portion, and the second support portion includes a second metal layer. The multiple pins are laterally separated from the first support portion and the second support portion, where in a top view, a ratio of a maximum length of the second metal layer to a maximum length of the package is greater than ⅔.

### BACKGROUND OF THE INVENTION

### 1. Field of the Invention

The present disclosure relates to the field of semiconductor technology, particularly to a package used for packaging semiconductor devices.

### 2. Description of the Prior Art

In the modern semiconductor field, with the increasing demand for high mobility devices, high electron mobility transistors (HEMTs) made from III-V materials (such as gallium nitride) are gaining attention, leading to a focus on their packaging methods. HEMTs can be mainly categorized into two types: Enhancement-Mode HEMT (E-Mode HEMT) and Depletion-Mode HEMT (D-Mode HEMT). Common packaging types for HEMTs include Transistor Outline package (TO), Dual Flat No lead package (DEN), and Quad Flat No lead package (QFN) and so forth.

Generally, the gate-source breakdown voltage of HEMTs (e.g., gallium nitride transistors) is about −10V to 7V. To prevent damage to the device caused by directly applying the highest external drive voltage to the high electron mobility transistor, protective electronic components are often placed between the HEMT package and the drive voltage to ensure the normal operation of the high electron mobility transistor.

However, additional protective electronic components require extra space on the circuit board layout and increase the overall complexity of the circuit design. Therefore, it is necessary to provide a package structure that integrates the high electron mobility transistor and its protective electronic components to overcome the aforementioned technical shortcomings.

In view of this, the present disclosure provides a package that can integrate a high electron mobility transistor and the protective electronic components to improve the technical deficiencies mentioned above.

### SUMMARY OF THE INVENTION

To achieve this purpose, the present disclosure discloses a package including a first support portion, a second support portion, and multiple pins. The first support portion includes a first upper metal layer and a first lower metal layer, wherein the first lower metal layer is connected to and overlaps with the first upper metal layer, corresponding to the position of the first upper metal layer. The second support portion is laterally separated from the first support portion, and the second support portion includes a second metal layer. The multiple pins are laterally separated from the first support portion and the second support portion, where in a top view, a ratio of a maximum length of the second metal layer to a maximum length of the package is greater than ⅔.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 shows the front surface and the back surface of a package according to one embodiment of the disclosure.

FIG. 2 is a top view of the front surface of a package according to another embodiment of the disclosure.

FIG. 3 shows the front surface and the back surface of a package according to one embodiment of the disclosure.

FIG. 4 shows a top view of the front surface and cross-sectional views corresponding to multiple section lines of the package according to one embodiment of the disclosure.

FIG. 5 is a cross-sectional view of a package according to one embodiment of the disclosure.

FIGS. 6A and 6B are top views of the front surface of a package including a cascode circuit structure according to one embodiment of the disclosure.

FIG. 7 is a circuit diagram of a package including a cascode circuit structure.

FIGS. 8A and 8B are top views of the front surface of a package including an enhancement-mode high electron mobility transistor according to one embodiment of the disclosure.

FIG. 9 is a circuit diagram of a package including an enhancement-mode high electron mobility transistor.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

Although this disclosure uses terms such as first, second, third, etc., to describe various components, parts, regions, layers, and/or sections, it should be understood that these components, parts, regions, layers, and/or sections should not be limited by these terms. These terms are merely used to distinguish one component, part, region, layer, and/or section from another, and do not inherently represent any precedence in sequence, nor do they represent the arrangement order or manufacturing sequence between one element and another. Therefore, within the scope of the specific embodiments of this disclosure, the first component, part, region, layer, or section discussed below can also be referred to by the terms of the second component, part, region, layer, or section.

The terms “about” or “substantially” mentioned in this disclosure typically indicate within 20% of a given value or range, preferably within 10%, and more preferably within 5%, or 3%, or 2%, or 18, or 0.5%. It should be noted that the quantities provided in the description are approximate quantities, that is, even without a specific explanation of “about” or “substantially”, the meaning of “about” or “substantially” can still be implied.

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

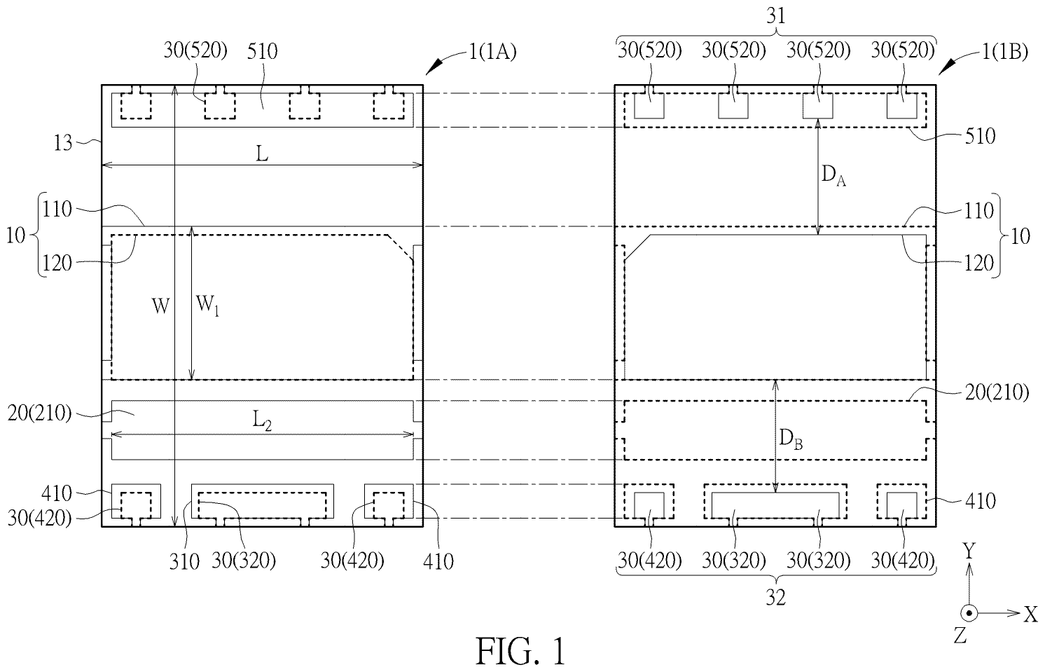

FIG. 1 schematically shows the front surface and the back surface of a package according to one embodiment of the disclosure, where the left side of FIG. 1 is the front top view 1A of a package 1 (also called semiconductor package), and the right side is the back view 1B of the package 1. Referring to FIG. 1, the package 1 includes at least a first support portion 10, a second support portion 20 laterally separated from the first support portion 10, and multiple pins 30 laterally separated from the first support portion 10 and the second support portion 20. The first support portion 10, second support portion 20, and multiple pins 30 can be separated along a certain direction (e.g., Y-axis direction) without direct contact. According to one embodiment, a molding structure 13 may additionally exist, which covers the front surface of the first support portion 10, the front surface of the second support portion 20, and the front surface of the multiple pins 30.

Referring to the front top view 1A and back view 1B of the package 1, the first support portion 10 includes a first upper metal layer 110 and a first lower metal layer 120. The first lower metal layer 120 is electrically connected to the first upper metal layer 110. According to one embodiment, the first lower metal layer 120 can be directly connected to and overlap with the first upper metal layer 110, and the position of first lower metal layer 120 corresponds to the position of the first upper metal layer 110. According to another embodiment, a connection portion (not shown) may additionally exist between the first upper metal layer 110 and the first lower metal layer 120, connecting the first upper metal layer 110 and the first lower metal layer 120. The front surface of the first upper metal layer 110 can be used to dispose semiconductor components or electronic components, such as transistors, diodes, resistors, or capacitors. The back surface of the first lower metal layer 120 can be used for external electrical connection or heat dissipation, which will be detailed later. The back surface area of the first lower metal layer 120 can be smaller than the front surface area of the first upper metal layer 110. According to one embodiment, when the package 1 includes the molding structure 13, the back surface of the first lower metal layer 120 is exposed from the molding structure 13, but the front surface of the first upper metal layer 110 is covered by the molding structure 13. According to one embodiment, the front surface and the back surface of the first upper metal layer 110 is covered by the molding structure 13, and the front surface of the first lower metal layer 120 is covered by the molding structure 13, while the back surface of the first lower metal layer 120 is exposed from the molding structure 13.

The second support portion 20 includes a second metal layer 210. The front surface of the second metal layer 210 can be used to dispose semiconductor components or electronic components, such as transistors, diodes, resistors, or capacitors. When the package 1 includes the molding structure 13, the entire front surface and back surface of the second metal layer 210 are covered by the molding structure 13, and the back surface is not exposed from the molding structure 13. In addition to supporting semiconductor or electronic components, the first upper metal layer 110 of the first support portion 10 and the second metal layer 210 of the second support portion 20 can also serve as fixed bonding locations for bonding wires in a wire bonding process, therefore, the area of the first upper metal layer 110 and the area of the second metal layer 210 need to be sufficient to meet these requirements. According to one embodiment, to satisfy the layout differences of electronic components due to different circuit requirements in the package 1, the first upper metal layer 110 and the second metal layer 210 must meet specific size requirements. For example, the ratio of the maximum length L2 of the second metal layer 210 to the maximum length L of the package 1 can be greater than ⅔. In this disclosure, the length of each component refers to the dimension parallel to the X-axis direction, and the width refers to the dimension parallel to the Y-axis direction, so the length and width of components are not determined based on their relative size.

In one embodiment, the multiple pins 30 can be used for internal and external electrical connections. The multiple pins 30 can be divided into groups, for example, divided into a first pin group 31 and a second pin group 32, and the first pin group 31 is disposed opposite second pin group 32 along the Y-axis direction. The first pin group 31 is located on one side of the package 1, while the second pin group 32 is located on the opposite side of the package 1. When the package 1 includes a molding structure 13, the back surfaces of the pins 30 is exposed from the molding structure 13.

Regarding the first pin group 31, it can include an upper metal layer extending along the X-axis direction, such as a fifth upper metal layer 510, and at least one fifth lower metal layer 520, for example, four laterally separated fifth lower metal layers 520. The fifth upper metal layer 510 can be used for wire bonding with internal components (also called internal electronic components) of the package 1. The fifth lower metal layer 520 can be used for external electrical connection. When the package 1 includes a molding structure 13, the front surface of the fifth upper metal layer 510 is covered by the molding structure 13 and will not be exposed from the molding structure 13, but the back surface of the fifth lower metal layer 520 is exposed from the molding structure 13.

Regarding the second pin group 32, according to one embodiment, it can include a third upper metal layer 310, a third lower metal layer 320, at least one fourth upper metal layer 410, and at least one fourth lower metal layer 420 (e.g., two fourth upper metal layers 410 and two fourth lower metal layers 420). The third upper metal layer 310 and two fourth upper metal layers 410 are located on the same side of the package 1. The fourth upper metal layers 410 are separated from each other and can be disposed at two sides of the third upper metal layer 310. The third lower metal layer 320 and the fourth lower metal layer 420 can correspond to and overlap with the third upper metal layer 310 and fourth upper metal layer 410, respectively. According to one embodiment, the number of each of the fifth upper metal layer 510, the fifth lower metal layer 520, the third upper metal layer 310, or the third lower metal layer 320 is not limited to one, but can be multiple. The quantity relationship between the fifth upper metal layer 510 and the fifth lower metal layer 520 can be one-to-many, many-to-one, or many-to-many with overlapping correspondence.

According to one embodiment, the manufacturing process for the package 1 in FIG. 1 can include the following steps exemplarily. First, obtain a metal sheet composed of materials such as silver, copper, iron, iron-nickel alloy, or copper alloy, with a surface that may include an electroplated layer, such as a silver layer. Next, perform a patterning process on the metal sheet. The patterning method includes applying stamping process on the metal sheet to create multiple parts. The patterning process may also include an etching process to form the lead frame for the first support portion 10, second support portion 20, and multiple pins 30. During the etching process, multiple parts of the metal sheet can be etched to form vertically connected upper layers and lower layers of different sizes or shapes, and formed the upper layers and the lower metal layers of the first support portion 10 and the multiple pins 30. In the etching step for forming the second support portion 20, the lower part of the metal sheet is etched to reduce the thickness of the metal sheet in this region, forming the second metal layer 210 of the second support portion 20. Subsequently, the electronic components are sequentially disposed on the first support portion 10, the second support portion 20, and/or the pins 30, and a molding structure that covers the lead frame and the electronic components is formed. Finally, the pins protruding from the molding structure are cut and trimmed to obtain the structure shown in FIG. 1. In this embodiment, the upper metal layers and the lower metal layers of the first support portion 10 and the multiple pins 30 are integrally formed from the same metal sheet through patterning. The formation of the upper metal layers and the lower metal layers is not limited to this method, and the upper metal layers and the lower metal layers can be made of different materials.

Referring to FIG. 1, in one embodiment, a ratio of a maximum width W1 of the first upper metal layer 110 to a maximum width W of the package 1 is from 30% to 50%, which is beneficial for the package design and the mounting of electronic component. According to one embodiment, the first support portion 10 is located between the first pin group 31 and the second support portion 20, and the second support portion 20 is located between the first support portion 10 and the second pin group 32. According to one embodiment, when a high electron mobility transistor is disposed on the front surface of the first support portion 10, because the first pin group 31 can be configured to be electrically connected to a high electric potential, such as drain potential, and the second pin group 32 can be configured to be electrically connected to a low electric potential, such as source potential or gate potential, in order to meet the voltage withstand requirements of the package 1, a shortest distance DA between the first pin group 31 and the first support portion 10 is greater than a shortest distance DB between the second pin group 32 and the first support portion 10.

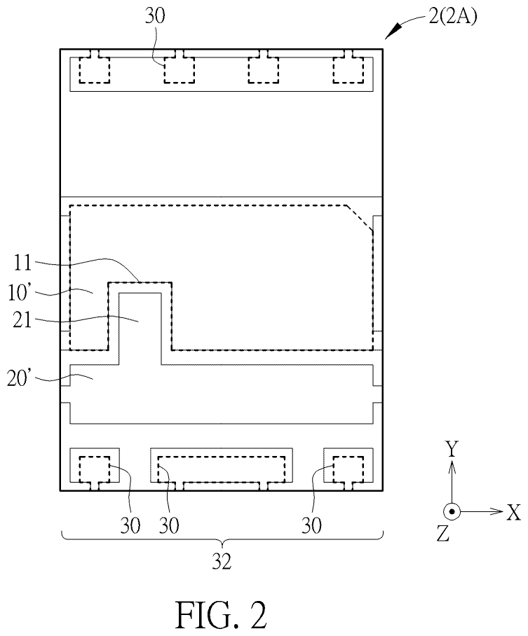

The front top view shape of the first support portion 10 and second support portion 20 is not limited to the shape shown in FIG. 1 and can be adjusted according to actual needs. Referring to FIG. 2, which is a front top view 2A of a package 2 according to another embodiment of the disclosure. The difference between the package 2 and the package 1 is that a second support portion 20′ can have a branch portion 21 extending along the Y-axis direction towards a first support portion 10′. The corresponding portion of the first support portion 10′ is recessed to form a recess portion 11 to accommodate the branch portion 21. The second support portion 20′ and first support portion 10′ are separated without direct electrical connection. In other embodiments, the number of the branch portion 21 and recess portion 11 are not limited to one and can be multiple, depending on actual requirements.

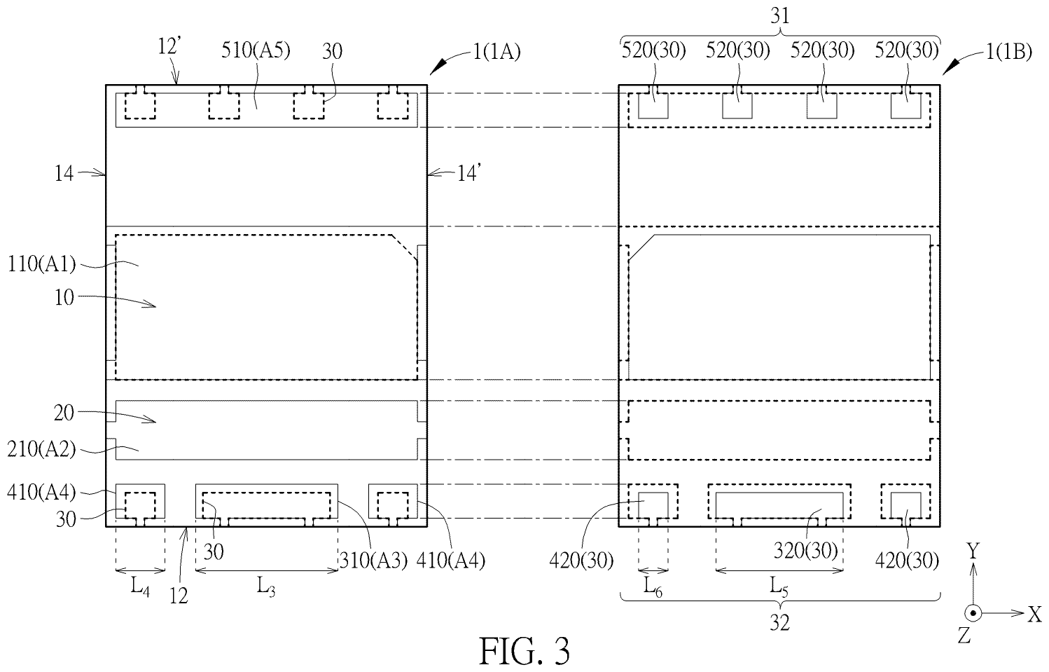

In one embodiment, referring to FIG. 3, the package 1 further includes two first side edges 12, 12′ oppositely disposed along the Y-axis direction, and two second side edges 14, 14′ oppositely disposed along the X-axis direction, where one end of each of the second side edges 14, 14′ is adjacent to the first side edge 12, and the other end is adjacent to the first side edge 12′.

Referring to FIG. 3 which includes a top view 1A of the front surface and a top view 1B of the back surface of the package 1 according to one embodiment of the disclosure, for the third upper metal layer 310 and fourth upper metal layer 410 of the second pin group 32, the third upper metal layer 310 and fourth upper metal layer 410 are separated from each other, allowing them to be configured to transmit different electrical signals; or they can be configured to transmit the same electrical signal or have the same electric potential through wire bonding. The third upper metal layer 310 and fourth upper metal layer 410 are located on the same side of the package 1, such as the first side edge 12. The two fourth upper metal layers 410 can be separated from each other and located on both sides of the third upper metal layer 310. A maximum length L3 of the third upper metal layer 310 is greater than twice a maximum length L4 of each fourth upper metal layer 410.

According to one embodiment, in the front top view 1A of the package 1, in addition to the third upper metal layer 310 and the fourth upper metal layer 410 located on the same side (i.e., on the first side edge 12), the multiple pins 30 can further include a fifth upper metal layer 510, located at the side opposite to the third upper metal layer 310 and two fourth upper metal layers 410 (i.e., on the first side edge 12′).

Referring to the back view 1B of FIG. 3 and the front top view 1A, the third lower metal layer 320 and the fourth lower metal layer 420 respectively correspond to and overlap with the third upper metal layer 310 and the fourth upper metal layer 410, and a maximum length Ls of the third lower metal layer 320 can be greater than twice a maximum length Le of each of the fourth lower metal layers 420.

According to one embodiment, referring to the front top view 1A of FIG. 3, the first support portion 10 is mainly used to support electronic components with larger top view dimensions, such as high electron mobility transistors. Depending on application requirements, the package 1 can include other electronic components disposed on the second support portion 20. Considering that the front top view area of the second support portion 20 is smaller than the front top view area of the first support portion 10, the second support portion 20 can be used to support electronic components with top view dimensions smaller than those of the high electron mobility transistors, such as low-voltage field-effect transistors, diodes, resistors, and/or capacitors. The upper metal layers of the multiple pins 30 can serve as wire bonding points or as direct soldering points for specific terminals of electronic components. To meet these requirements, a front surface area A1 of the first upper metal layer 110 is larger than a front surface area A2 of the second metal layer 210, and the front surface area A2 of the second metal layer 210 is larger than a front surface area of at least one of the multiple pins 30. For example, the front surface area A2 of the second metal layer 210 is larger than a front surface area A3 of the third upper metal layer 310, larger than a front surface area A4 of the fourth upper metal layer 410, and/or larger than a front surface area A5 of the fifth upper metal layer 510. Since the third upper metal layer 310 and the fourth upper metal layer 410 are mainly used as wire bonding points or as direct soldering points for specific terminals of electronic components, their individual front surface areas can be smaller than the front surface area of the first support portion 10 and the front surface area of the second support portion 20. According to one embodiment, the sum of the front surface area A3 of the third upper metal layer 310 and the front surface area A4 of the fourth upper metal layer 410 of the second pin group 32 is smaller than the front surface area A2 of the second metal layer 210. In addition, the shape of the third upper metal layer 310 and the fourth upper metal layer 410 can be adjusted according to actual requirements.

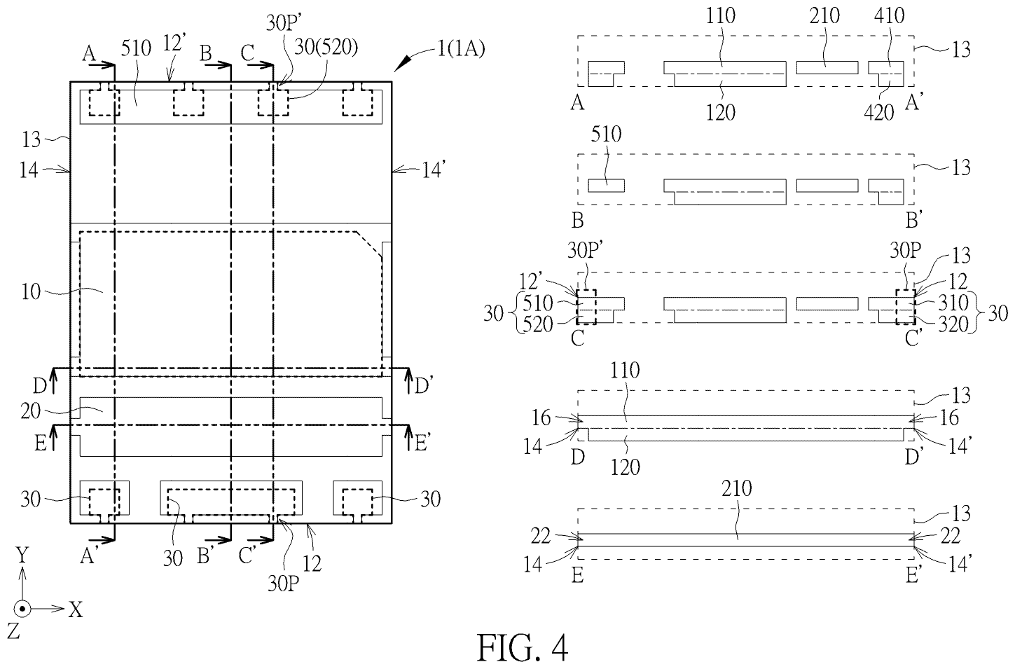

FIG. 4 is a front top view of the package 1 and cross-sectional views corresponding to each section line. The front top view 1A is substantially equivalent to the front top view 1A shown in FIG. 1, and the cross-sections A-A′ to E-E′ correspond to the section lines A-A′ to E-E′ in the front top view 1A.

Referring to the cross-section A-A′ in FIG. 4, a width of the first upper metal layer 110 of the first support portion 10 along the Y-axis direction is larger than a width of the first lower metal layer 120, and a width of the fourth upper metal layer 410 along the Y-axis direction is larger than a width of the fourth lower metal layer 420 along the Y-axis direction. Additionally, the back surface of the second metal layer 210 is higher than the back surface of the first lower metal layer 120. Referring to the cross-section B-B′ in FIG. 4, a back surface of the fifth upper metal layer 510 is higher than the back surface of the first lower metal layer 120. Referring to the cross-section C-C′ and front top view 1A, the fifth upper metal layer 510 and the fifth lower metal layer 520 extend to the first side edge 12′ along the Y-axis direction, becoming the pins 30 located on the first side edge 12′. The portions of the fifth upper metal layer 510 and the fifth lower metal layer 520 that extend and protrude towards the first side edge 12′ can form protrusion portions 30P′ of the pins 30, and one edge of the protrusion portion 30P′ can be aligned with the first side edge 12′. The third upper metal layer 310 and the third lower metal layer 320 extend to the first side edge 12 along the Y-axis direction, becoming the pins 30 located on the first side edge 12. The portions of the third upper metal layer 310 and the third lower metal layer 320 that extend and protrude towards the first side edge 12 can form the protrusion portions 30P of the pins 30, and one edge of the protrusion portion 30P can be aligned with the first side edge 12.

Referring to the cross-section D-D′ in FIG. 4, opposite ends of the first upper metal layer 110 of the first support portion 10 form two protrusion portions 16, respectively extending along the X-axis direction towards the second side edges 14 and 14′, and respectively aligned with the two second side edges 14 and 14′. Referring to the cross-section E-E′, the second support portion 20 includes two protrusion portions 22 respectively extending from opposite end regions of the second metal layer 210 along the X-axis direction towards the two second side edges 14 and 14′, and respectively aligned with the two second side edges 14 and 14′. For the protrusion portions 16 and 22 shown in cross-sections D-D′ and E-E′, during the preparation of protrusion portions 16 and 22, the corresponding portions of the lead frame are half-etched so that the protrusion portions 16 and 22 have a reduced thickness. Additionally, before forming the molding structure 13, the protrusion portions 16 and 22 can serve as portions of a support structure, allowing the first support portion 10 and second support portion 20 to be supported by the outer frame of the lead frame through the support structure. After forming the molding structure 13, the support structure protruding from the molding structure 13 will be cut and trimmed to form the protrusion portions 16 and 22.

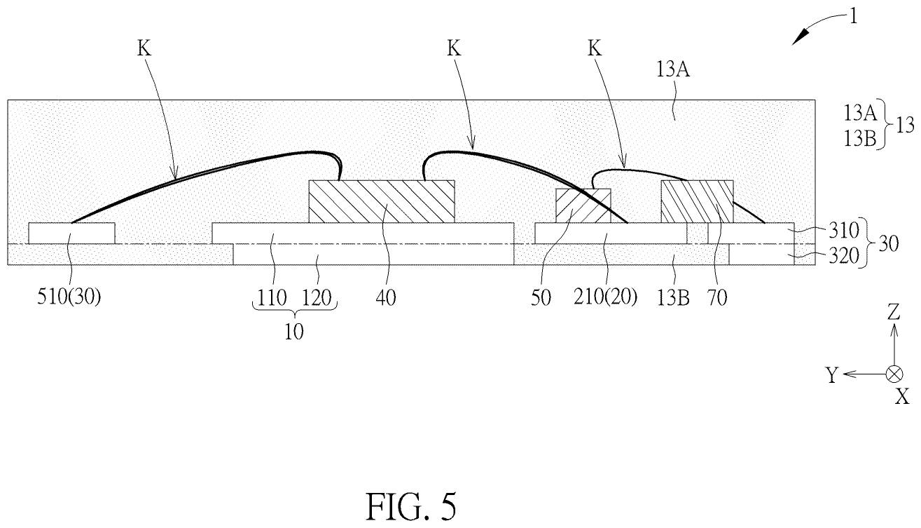

FIG. 5 is a cross-sectional view of the package 1 according to one embodiment of the disclosure, approximately corresponding to the cross-section B-B′ in FIG. 4. According to one embodiment as shown in FIG. 5, the package 1 can further include multiple electronic components and bonding wires, such as a high electron mobility transistor 40, a field-effect transistor 50, and a resistor 70, along with multiple conductive connection lines K. Additionally, the molding structure 13 can include an integrally formed structure including an upper molding structure 13A and a lower molding structure 13B. The upper molding structure 13A completely covers the front surface of the first upper metal layer 110 of the first support portion 10, the front surface of the second metal layer 210 of the second support portion 20, the upper metal layers 310 and 510 of the multiple pins 30, the high electron mobility transistor 40, the field-effect transistor 50, and the resistor 70, and encapsulates the conductive connection lines K. The lower molding structure 13B covers the back surface of the second metal layer 210 of the second support portion 20 and the back surface of the fifth metal layer 510, thereby filling the space among the entire back surface of the second metal layer 210 of the second support portion 20, the back surface of the first lower metal layer 120, and the back surface of third lower metal layer 320. In contrast, since the first lower metal layer 120 of the first support portion 10 and the third lower metal layer 320 of the pins 30 are configured for electrical connection to external circuits, the back surfaces of the first lower metal layer 120 and the third lower metal layer 320 are exposed from the lower molding structure 13B. When the thickness of the lower molding structure 13B is less than the thickness of the first lower metal layer 120 and third lower metal layer 320, the back surfaces and portions of the side surfaces of the first lower metal layer 120 and third lower metal layer 320 are exposed from the lower molding structure 13B.

According to one embodiment, before forming the molding structure 13, a wire bonding process is performed to electrically connect the electronic components disposed on the first support portion 10, the second support portion 20, and the pins 30. For example, a wire bonding machine can be used to bond one terminal of at least one wire K to an electronic component, and to bond the other terminal to a metal layer on the first support portion 10, second support portion 20, or pins 30, with the wire K being made of conductive materials such as gold or copper. After performing the wire bonding process, the transfer molding process is performed so that the molding material is heated and injected into a mold to cover the first support portion 10, second support portion 20, multiple pins 30, and electronic components, thereby forming the molding structure 13. The molding material can be primarily composed of epoxy resin or other suitable polymers.

The package of this disclosure can be applied to Dual Flat No-lead (DEN) packaging for the high electron mobility transistor. The high electron mobility transistor can be an enhancement-mode high electron mobility transistor (E-HEMT) or a depletion-mode high electron mobility transistor (D-HEMT), where the enhancement-mode or depletion-mode high electron mobility transistor can be a GaN-based high electron mobility transistor or other suitable III-V semiconductor high electron mobility transistors.

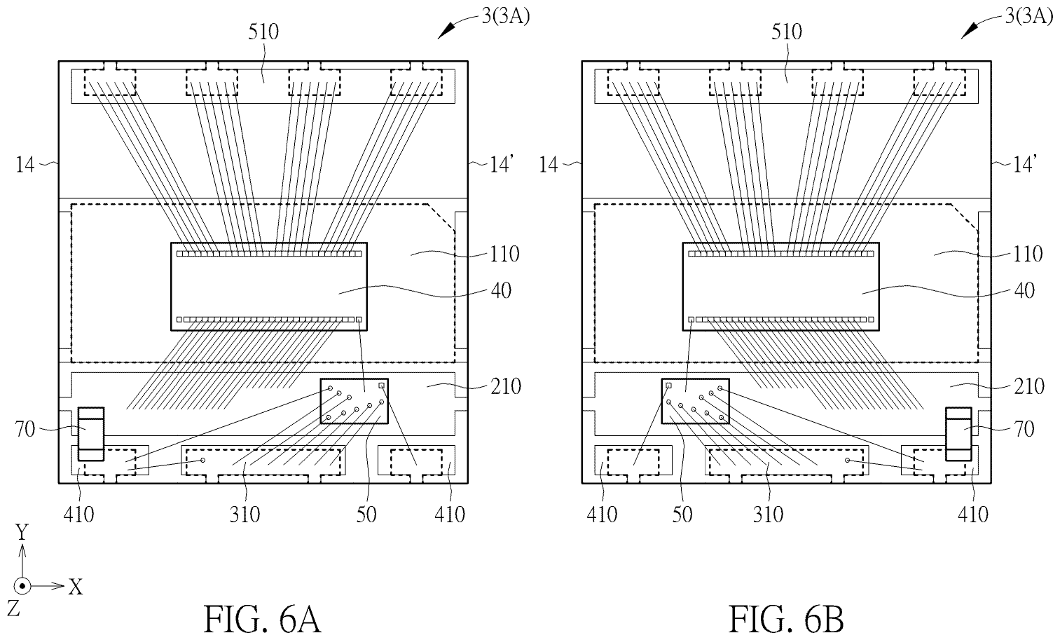

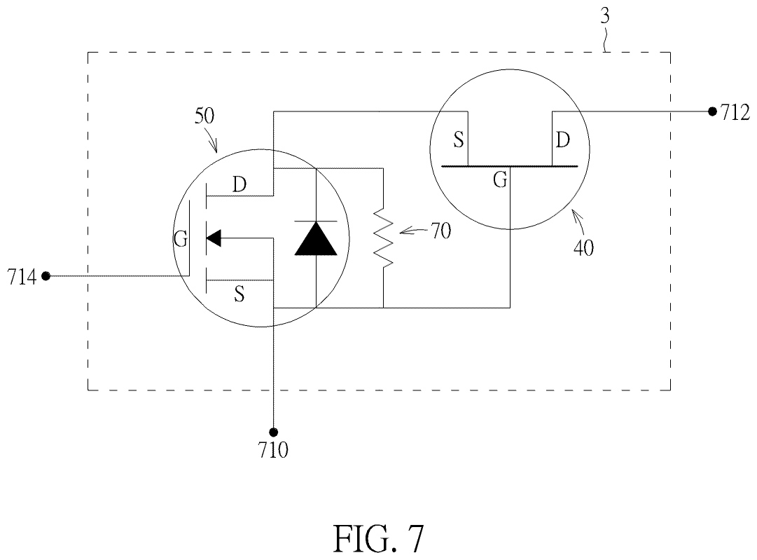

Referring to FIGS. 6A, 6B, and 7. FIG. 6A shows a front top view 3A of a package 3 with a cascode circuit structure. FIG. 7 shows the corresponding circuit diagram. The difference between the package 3 and the package 1 is that the package 3 additionally includes a depletion-mode high electron mobility transistor 40, a field-effect transistor 50, and a resistor 70. The depletion-mode high electron mobility transistor 40 is disposed on the first upper metal layer 110, having a source, a gate, and a drain, where the source is electrically connected to the second metal layer 210 via a bonding wire, the gate is electrically connected to the field-effect transistor 50 via a bonding wire, and the drain is electrically connected to the fifth upper metal layer 510 via a bonding wire. The field-effect transistor 50 is disposed on the second metal layer 210, having a source, a gate, and a drain, where the source of the field-effect transistor 50 is electrically connected via different bonding wires to the gate of the depletion-mode high electron mobility transistor 40 and the third upper metal layer 310, and the gate of the field-effect transistor 50 is electrically connected to the fourth upper metal layer 410 adjacent to the second side edge 14′. The resistor 70 is disposed adjacent to the second side edge 14, and two terminals of the resistor 70 are respectively bridged between the second metal layer 210 and the fourth upper metal layer 410 adjacent to the second side edge 14.

According to one embodiment, to accommodate different applications, the multiple pins 30 of the D-HEMT package can include two fourth upper metal layers 410 that are not adjacent to each other and are respectively located on two sides of the third upper metal layer 310. This increases the flexibility of electronic component layout configuration, as the electronic components are less constrained by pin positions. For example, in another embodiment, referring to FIG. 6B, the electronic component configuration is similar to FIG. 6A. The main difference is that the field-effect transistor 50 is disposed adjacent to the second side edge 14, and the gate of the field-effect transistor 50 is electrically connected to the fourth upper metal layer 410 adjacent to the second side edge 14 via a bonding wire. Additionally, the resistor 70 is disposed adjacent to the second side edge 14′, with two terminals of the resistor 70 bridging between the second metal layer 210 and the fourth upper metal layer 410 adjacent to the second side edge 14′.

The corresponding circuit diagram for the structures shown in FIGS. 6A and 6B is illustrated in FIG. 7. Referring to FIG. 7, the drain D of the depletion-mode high electron mobility transistor 40 is electrically connected to a drain terminal 712 of the package 3. The gate G of the depletion-mode high electron mobility transistor 40 is electrically connected to the source S of the field-effect transistor 50 and one terminal of the resistor 70, and the source S of the field-effect transistor 50 is electrically connected to a source terminal 710 of the package 3. The source S of the depletion-mode high electron mobility transistor 40 is electrically connected to the drain D of the field-effect transistor 50 and the other terminal of the resistor 70. The gate G of the field-effect transistor 50 is electrically connected to the gate terminal 714 of the package 3. By integrating the depletion-mode high electron mobility transistor 40 and the field-effect transistor 50 within the package 3, the space required for traces on the circuit board, which electrically connect individual components, is reduced. Moreover, the package 3 directly integrates the depletion-mode high electron mobility transistor 40 and field-effect transistor 50 of the cascode structure, allowing users to directly use the package 3 to achieve E-mode HEMT functionality without the need for additional external electronic components.

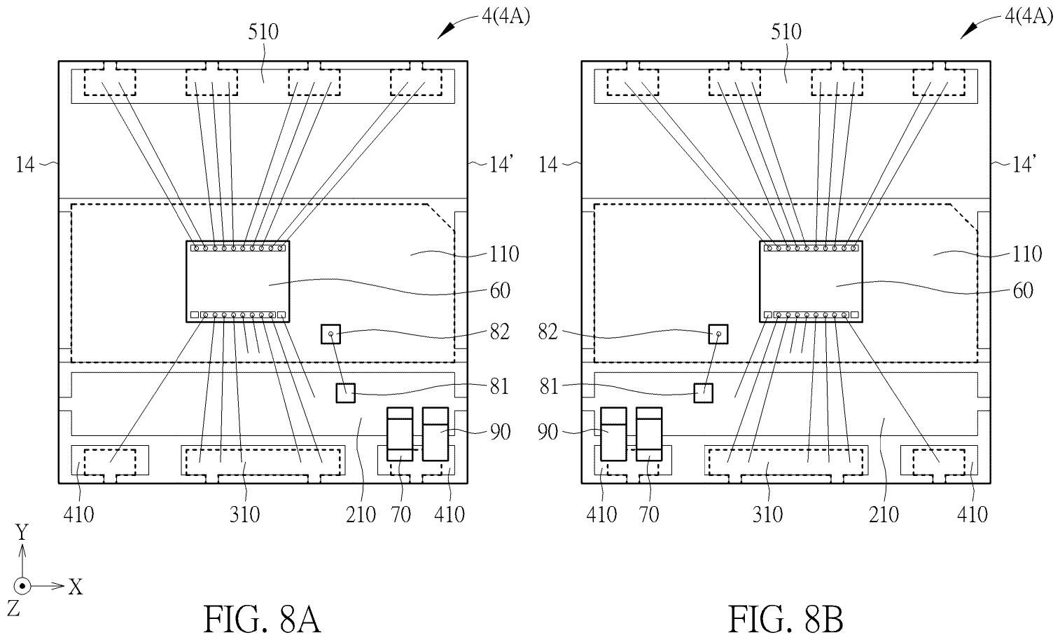

Referring to FIG. 8A, which is a front top view 4A of a package 4 for an enhancement-mode high electron mobility transistor. The package 4 includes an enhancement-mode high electron mobility transistor 60, a first Zener diode 81, a second Zener diode 82, a resistor 70, and a capacitor 90. The enhancement-mode high electron mobility transistor 60 is disposed on the first upper metal layer 110, having a source, a gate, and a drain. The source is electrically connected to the third upper metal layer 310 via a bonding wire, the gate is electrically connected to the second metal layer 210 via a bonding wire, and the drain is electrically connected to the fifth upper metal layer 510 via a bonding wire. The first Zener diode 81 is disposed on the second metal layer 210, with its cathode electrically connected to the second metal layer 210. The second Zener diode 82 is disposed on the first upper metal layer 110, with its cathode electrically connected to the first upper metal layer 110. The anode of the first Zener diode 81 can be further electrically connected to the anode of the second Zener diode 82. The package 4 also includes an RC circuit for filtering signals, for example, by bridging each of the resistor 70 and the capacitor 90 between the second metal layer 210 and the fourth upper metal layer 410.

The gate-source breakdown voltage of an enhancement-mode high electron mobility transistor, such as an enhancement-mode gallium nitride transistor, can withstand approximately-10V to 7V, while the drive voltage of a typical power conversion control circuit output is around OV to 20V. When the highest external drive voltage is directly applied to the enhancement-mode high electron mobility transistor, the transistor is likely to be damaged. Therefore, a protection circuit is often placed between the high electron mobility transistor and the drive voltage to ensure normal operation of the high electron mobility transistor. By integrating the enhancement-mode high electron mobility transistor 60 and the protection circuit components within the package 4, the space required for traces on the circuit board, which electrically connect individual components, are reduced. According to one embodiment, when the drive voltage of a driving signal exceeds the normal operating voltage range of the enhancement-mode high electron mobility transistor 60, the first Zener diode 81, second Zener diode 82, resistor 70, and capacitor 90 are activated to protect the enhancement-mode high electron mobility transistor 60 from burnout and maintain normal operation of the enhancement-mode high electron mobility transistor 60. In other words, the first Zener diode 81, second Zener diode 82, resistor 70, and capacitor 90 serve as the protection circuit for the enhancement-mode high electron mobility transistor 60.

According to one embodiment, to accommodate different applications, the multiple pins 30 of the E-HEMT package can include two fourth upper metal layers 410 that are not adjacent to each other and are disposed on both sides of the third upper metal layer 310. This increases the flexibility of electronic component layout, as the electronic components are less constrained by pin positions. For example, in another embodiment, referring to FIG. 8B, the electronic component configuration is similar to FIG. 8A, with the main difference being that the gate of the enhancement-mode high electron mobility transistor 60 is electrically connected to the fourth upper metal layer 410 adjacent to the second side edge 14′ via a bonding wire. Additionally, the two terminals of each of the resistor 70 and the two terminals of the capacitor 90 are bridged between the second metal layer 210 and the fourth upper metal layer 410 adjacent to the second side edge 14.

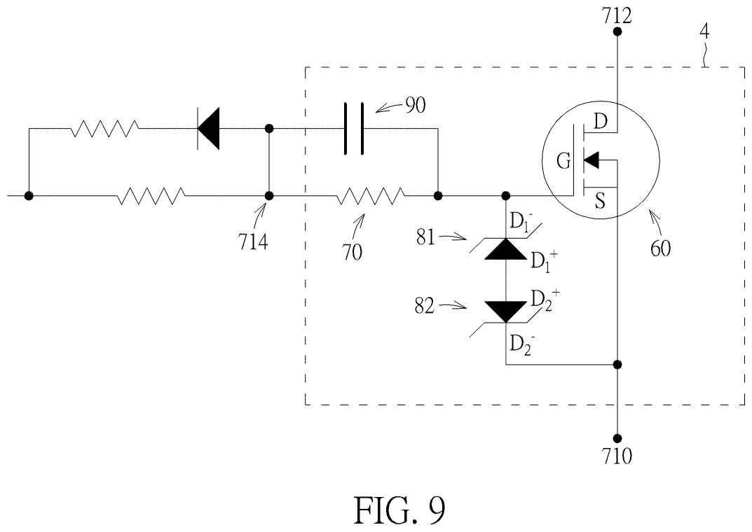

The corresponding circuit diagram for the structures shown in FIGS. 8A and 8B is illustrated in FIG. 9. Referring to FIG. 9, the drain D of the enhancement-mode high electron mobility transistor 60 is electrically connected to a drain terminal 712 of the package 4, the source S and the cathode D₂⁻ of the second Zener diode 82 are electrically connected to a source terminal 710 of the package 4, the gate G and the cathode D₁⁻ of the first Zener diode 81 are electrically connected, and then connected to the RC circuit formed by the parallel connection of resistor 70 and capacitor 90, and further connected to a gate terminal 714 of the package 4. The first Zener diode 81 and second Zener diode 82 are connected in reverse series, with the anode D₁⁺ of the first Zener diode 81 electrically connected to the anode D₂⁺ of the second Zener diode 82. The package 4, which includes the enhancement-mode high electron mobility transistor 60, can be further electrically connected to an external circuit, for example, through the gate terminal 714 of the package 4 to an external circuit including resistors and diodes.

The packages 1, 2, 3, and 4 of this disclosure can be used in packaging types such as DEN or QFN.

Although detailed explanations of the embodiments and their advantages have been provided, it should be understood that various changes, substitutions, and modifications can be made within the spirit of the disclosure and the scope defined by the patent claims. The described embodiments are solely for illustrative purposes and not for limiting the disclosure. The protection scope shall be determined by the appended patent claims. Those skilled in the art can make minor modifications and refinements within the spirit and scope of the disclosure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package, comprising:
a first support portion comprising a first upper metal layer and a first lower metal layer, wherein the first lower metal layer is connected to and overlaps with the first upper metal layer, and the first lower metal layer is disposed corresponding to the first upper metal layer;
a second support portion laterally separated from the first support portion, wherein the second support portion comprises a second metal layer; and
a plurality of pins laterally separated from the first support portion and the second support portion,
wherein, in a top view, a ratio of a maximum length of the second metal layer to a maximum length of the package is greater than ⅔.

2. The package according to claim 1, wherein, in a top view, a front surface area of the second metal layer is smaller than a front surface area of the first upper metal layer, and the front surface area of the second metal layer is larger than a front surface area of at least one of the plurality of pins.

3. The package according to claim 1, wherein, in a top view, the package further comprises:
two opposite first side edges;
two opposite second side edges adjacent to each of the first side edges,
wherein two protrusion portions respectively extends from two opposite end portions of the second metal layer towards the two opposite second side edges, and respectively aligned with the opposite second side edges.

4. The package according to claim 1, wherein the plurality of pins further comprise a first pin group and a second pin group opposite to the first pin group, and the second support portion is located between the first support portion and the second pin group, wherein a shortest distance between the first pin group and the first support portion is greater than a shortest distance between the second pin group and the first support portion.

5. The package according to claim 1, further comprising a molding structure, wherein a back surface of the first lower metal layer and back surfaces of the plurality of pins are exposed from the molding structure.

6. The package according to claim 5, wherein the molding structure comprises an upper molding structure and a lower molding structure, the upper molding structure covers a front surface of the first support portion, a front surface of the second support portion, and front surfaces of the plurality of pins, and the lower molding structure covers an entire back surface of the second metal layer.

7. The package according to claim 1, wherein a ratio of a maximum width of the first upper metal layer to a maximum width of the package is from 30% to 50%.

8. The package according to claim 1, wherein the plurality of pins comprise a third upper metal layer and at least one fourth upper metal layer, the third upper metal layer and the at least one fourth upper metal layer are located on a same side of the package, and a maximum length of the third upper metal layer is greater than twice a maximum length of the fourth upper metal layer.

9. The package according to claim 8, wherein a sum of a front surface area of the third upper metal layer and a front surface area of the at least one fourth upper metal layer is smaller than the surface area of the second metal layer.

10. The package according to claim 8, wherein the at least one fourth upper metal layer comprises two fourth upper metal layers separated from each other and respectively located at two sides of the third upper metal layer.

11. The package according to claim 8, further comprising a third lower metal layer and at least one fourth lower metal layer, respectively corresponding to and overlapping with the third upper metal layer and the at least one fourth upper metal layer, wherein a maximum length of the third lower metal layer is greater than twice a maximum length of the fourth lower metal layer.

12. The package according to claim 1, wherein the package is applied to a dual flat no-lead (DEN) package.

13. The package according to claim 8, wherein the at least one fourth upper metal layer comprises two fourth upper metal layers separated from each other, and the plurality of pins comprise a fifth upper metal layer opposite to the third upper metal layer and the two fourth upper metal layers, and the package further comprises:
a depletion-mode high-electron-mobility transistor (HEMT) disposed on the first upper metal layer and comprising a source, a drain, and a gate, the source being electrically connected to the second metal layer, and the drain being electrically connected to the fifth upper metal layer;
a field-effect transistor (FET) disposed on the second metal layer and comprising a drain, a source, and a gate, the drain being electrically connected to the second metal layer, the source being electrically connected to the gate of the depletion-mode HEMT and the third upper metal layer, and the gate being electrically connected to one of the two fourth upper metal layers; and
a resistor bridged between the second metal layer and another one of the two fourth upper metal layers.

14. The package according to claim 8, wherein the at least one fourth upper metal layer comprises two fourth upper metal layers separated from each other, the plurality of pins further comprise a fifth upper metal layer opposite to the third upper metal layer and the two fourth upper metal layers; and the package further comprises:
an enhancement-mode high-electron-mobility transistor (HEMT) disposed on the first upper metal layer, comprising a source, a gate, and a drain, the source being electrically connected to the third upper metal layer, the gate being electrically connected to the second metal layer, and the drain being electrically connected to the fifth upper metal layer;
a first Zener diode disposed on the second metal layer, one terminal of the first Zener diode being electrically connected to the second metal layer;
a second Zener diode disposed on the first upper metal layer, one terminal of the second Zener diode being electrically connected to the first upper metal layer; and
a resistor and a capacitor respectively bridged between the second metal layer and one of the two fourth upper metal layers.

15. The package according to claim 13, wherein the depletion-mode high-electron-mobility transistor is a GaN-based high-electron-mobility transistor.

16. The package according to claim 14, wherein the enhancement-mode high-electron-mobility transistor is a GaN-based high-electron-mobility transistor.
